(19) United States
(12) Patent Application Publication
(10) Pub. No.: US 2024/0322518 A1
(43) Pub. Date: Sep. 26, 2024

(54) Laser Irradiation Device, Information Processing Method, and Method for Generating Learning Model

(71) Applicant: JSW Aktina System Co., Ltd., Yokohama-shi, Kanagawa (JP)

(72) Inventors: Kenichi Ohmori, Yokohama-shi, Kanagawa (JP); Yuzaburo Ohta, Yokohama-shi, Kanagawa (JP); Rei Matsushita, Yokohama-shi, Kanagawa (JP)

(21) Appl. No.: 18/580,485

(22) PCT Filed: Mar. 22, 2022
(86) PCT No.: PCT/JP2022/012980

§ 371 Date: Jan. 18, 2024

(30) Foreign Application Priority Data
Aug. 4, 2021 (JP) 2021-128501

(51) Int. Cl. H01S 3/10; B23K 26/03; B23K 26/073

(52) U.S. Cl. CPC H01S 3/10069; B23K 26/032; B23K 26/073

(57) ABSTRACT

Provided is a laser irradiation device including: a laser light source that emits laser light; and a control unit that performs control relating to irradiation of a substrate with laser light. The control unit acquires operation parameters including a detection value from a detection unit provided in the laser irradiation device, derives predicted quality information by inputting the acquired operation parameters to a learning model that outputs predicted quality information of a product including the substrate irradiated with the laser light in a case where the operation parameters are input, and outputs the derived predicted quality information and the acquired operation parameters in association with each other.

### CROSS-REFERENCE TO RELATED APPLICATION

This application claims the benefit of the priority right of PCT International Application No. PCT/JP2022/012980 which has an International filling date of Mar. 22, 2022, which is incorporated by reference in its entirety.

### FIELD

The present invention relates to a laser irradiation device, an information processing method, a recording medium recording a program in a readable manner, and a method for generating a learning model.

### BACKGROUND

A laser annealing device configured to form a polycrystalline silicon thin film is known (for example, Patent Document 1).

The laser annealing device described in Patent Document 1 includes a waveform shaping device that shapes a waveform of a laser light pulse, and the polycrystalline silicon thin film is formed by irradiating an amorphous silicon film with laser light shaped in a line shape by the waveform shaping device (for example, refer to Japanese Patent Laid-Open Publication No. 2012-15545).

However, the laser annealing device disclosed in Patent Document 1 does not consider a configuration in which quality information (predicted quality information) of a product manufactured by the laser annealing device is estimated on the basis of operation parameters of the laser annealing device.

### SUMMARY

The invention has been made in consideration of the circumstance, and an object thereof is to provide a laser irradiation device and the like that estimate quality information (predicted quality information) of a product manufactured by a laser annealing device on the basis of operation parameters of the laser annealing device.

A laser irradiation device according to an aspect, including: a laser light source that emits laser light; and a control unit that performs control relating to irradiation of a substrate with laser light. The control unit acquires operation parameters including a detection value from a detection unit provided in the laser irradiation device, derives predicted quality information by inputting the acquired operation parameters to a learning model that outputs predicted quality information of a product including the substrate irradiated with the laser light in a case where the operation parameters are input, and outputs the derived predicted quality information and the acquired operation parameters in association with each other.

An information processing method according to another aspect, causing a computer to execute processing of: acquiring operation parameters including a detection value from a detection unit provided in a laser irradiation device: deriving predicted quality information by inputting the acquired operation parameters to a learning model that outputs predicted quality information of a product including a substrate irradiated with laser light in a case where operation parameters are input; and outputting the derived predicted quality information and the acquired operation parameters in association with each other.

A program according to still another aspect, causing a computer to execute processing of: acquiring operation parameters including a detection value from a detection unit provided in a laser irradiation device: deriving predicted quality information by inputting the acquired operation parameters to a learning model that outputs predicted quality information of a product including a substrate irradiated with laser light in a case where operation parameters are input; and outputting the derived predicted quality information and the acquired operation parameters in association with each other.

A method for generating a learning model according to still another aspect, including: acquiring operation parameters including a detection value from a detection unit provided in a laser irradiation device; acquiring quality information of a product including a substrate processed by a laser irradiation device controlled by using the operation parameters; and generating a learning model that outputs the quality information of the product including the substrate processed by the laser irradiation device in a case where the operation parameters are input by using training data including question data consisting of the acquired operation parameters, and answer data consisting of the acquired quality information.

According to the invention, it is possible to provide a laser irradiation device and the like that estimate quality information (predicted quality information) of a product manufactured by a laser annealing device on the basis of operation parameters of the laser annealing device.

### BRIEF DESCRIPTION OF THE DRAWINGS

FIG. 1 is a view illustrating a system configuration example including a laser annealing device and the like according to Embodiment 1.

FIG. 2 is a view illustrating a configuration example of the laser annealing device.

FIG. 3 is a view illustrating a configuration example of a control device included in the laser annealing device.

FIG. 4 is an explanatory view illustrating an example of a learning model.

FIG. 5 is a flowchart illustrating an example of a procedure of the control unit (when training a learning model).

FIG. 6 is a flowchart illustrating an example of a procedure of the control unit (when operating the learning model).

FIG. 7 is a view illustrating an example of a management screen of the laser annealing device.

FIG. 8 is a flowchart illustrating an example of a procedure of the control unit according to Embodiment 2 (when deriving operation parameters).

FIG. 9 is a process cross-sectional view illustrating a method for manufacturing a semiconductor device according to another embodiment (a method for manufacturing a semiconductor device).

FIG. 10 is a process cross-sectional view illustrating a method for manufacturing a semiconductor device according to the other embodiment (the method for manufacturing a semiconductor device).

FIG. 11 is a process cross-sectional view illustrating a method for manufacturing a semiconductor device according to the other embodiment (the method for manufacturing a semiconductor device).

FIG. 12 is a process cross-sectional view illustrating a method for manufacturing a semiconductor device according to the other embodiment (the method for manufacturing a semiconductor device).

FIG. 13 is a process cross-sectional view illustrating a method for manufacturing a semiconductor device according to the other embodiment (the method for manufacturing a semiconductor device).

### DESCRIPTION OF EMBODIMENTS

### Embodiment 1

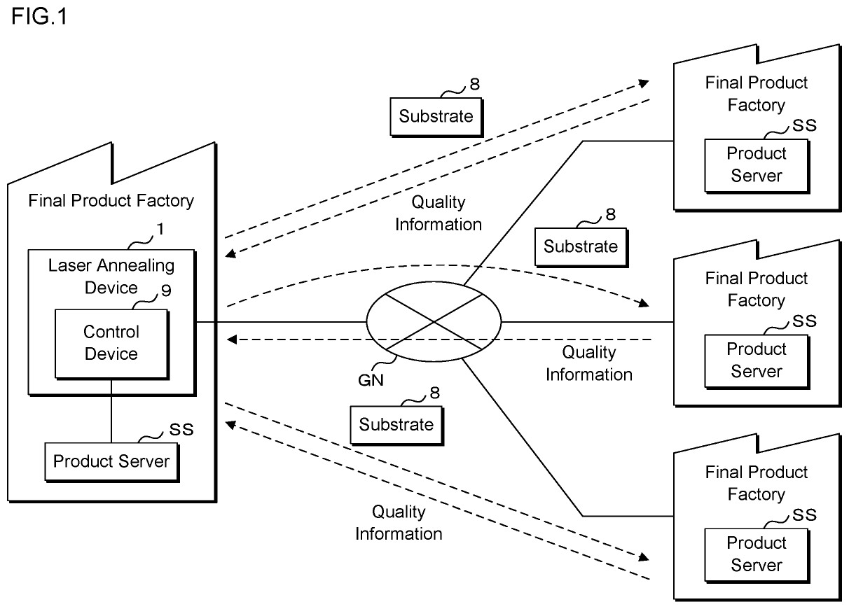

Hereinafter, an embodiment of the invention will be described. FIG. 1 is a view illustrating a system configuration example including a laser annealing device and the like according to Embodiment 1. The laser annealing device 1 (laser irradiation device) is an excimer laser anneal (ELA) device that forms, for example, a low temperature poly-silicon (LTPS) film.

The laser annealing device 1 is mounted in a manufacturing factory that manufactures a substrate (substrate 8) for semiconductors such as a glass substrate in which a polycrystalline silicon film is formed, and the manufactured substrate 8 is shipped to a final product factory that manufactures a final product incorporated with the substrate 8. In the final product factory, a product server SS that retains and manages quality information of the final product is mounted.

A control device 9 included in the laser annealing device 1 acquires quality information of a final product from the product server SS, for example, through an external network GN such as the Internet. A quality information acquisition system that acquires the quality information of the final product is constituted by the laser annealing device 1 including the control device 9 and a plurality of the product servers SS which are connected in a communication possible manner through the external network GN as described above. Each of the product servers SS and the laser annealing device 1 may be installed in the same site (final product factory) without limitation to a case where the product server SS and the laser annealing device 1 are located at different sites. In this case, the product server SS and the laser annealing device 1 are connected to each other by a LAN (in-factory network) of the final product factory.

The quality information includes a yield rate of the substrate 8 incorporated into the final product, frequency of occurrence of a defect, defective position information, evaluation information, and the like. The control device 9 performs various kinds of processing such as generation of a learning model 921 to be described later by using the acquired quality information of the final product, estimation of quality information (predicted quality information) of the final product in a production stage of the substrate 8 by using the learning model 921. In a case where management references of the quality information of the final product are different in a plurality of final product factories, the control device 9 may generate and operate the learning model 921 for every final product factory (from which the substrate 8 is shipped). Alternatively, the learning model 921 that is universally applicable to individual final products may be generated by using information obtained by normalizing, standardizing, or averaging a plurality of pieces of the quality information acquired from the plurality of final product factories.

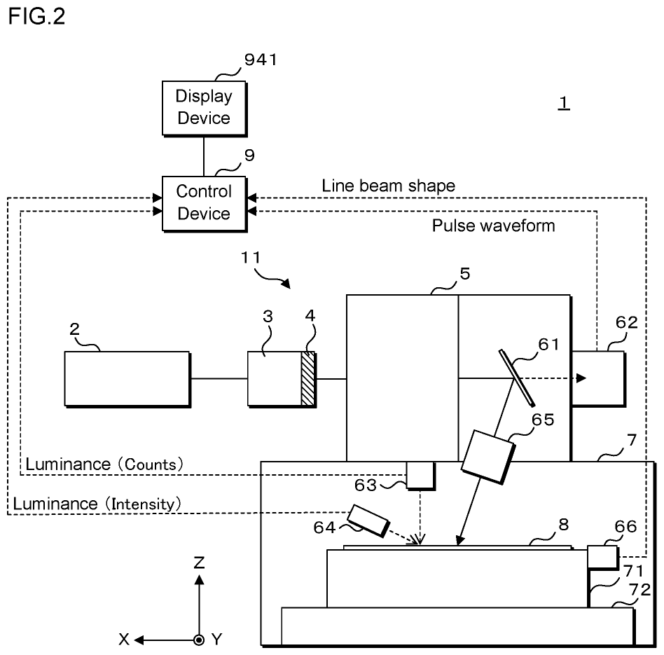

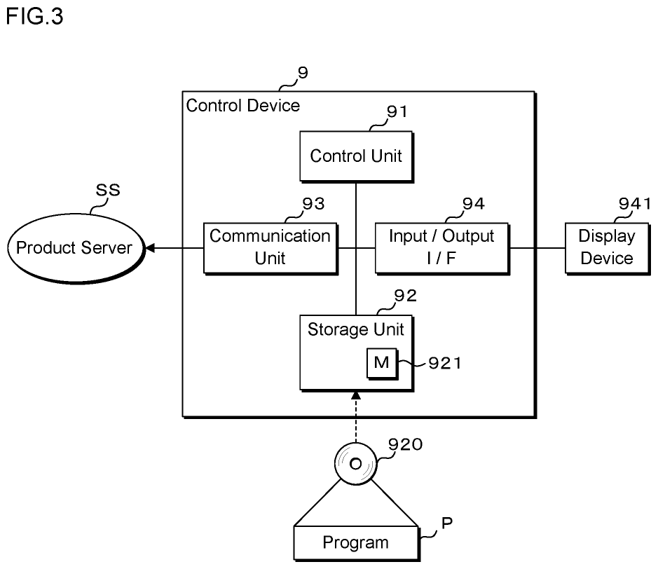

FIG. 2 is a view illustrating a configuration example of the laser annealing device. FIG. 3 is a view illustrating a configuration example of the control device 9 included in the laser annealing device. The laser annealing device 1 irradiates a silicon film formed on the substrate 8 with laser light. According to this, it is possible to convert a non-crystalline silicon film (an amorphous silicon film: a-Si film) into a polycrystalline silicon film (polysilicon film: p-Si film). The substrate 8 is a substrate for semiconductors.

As illustrated in the drawings in this embodiment, in an XYZ three-dimensional orthogonal coordinate system, a Z-direction becomes a vertical direction and is a direction orthogonal to the substrate 8. An XY-plane is a plane parallel to a surface on which the silicon film of the substrate 8 is formed. For example, an X-direction becomes a longitudinal direction of the substrate 8 having a rectangular shape, and a Y-direction becomes a lateral direction of the substrate 8. In a case of using a O-axis stage 71 rotatable from 0° to 90° around the Z-axis, the X-direction becomes the lateral direction of the substrate 8 and the Y-direction becomes the longitudinal direction of the substrate 8.

The laser annealing device 1 includes an annealing optical system 11, a laser irradiation chamber 7, and the control device 9. The laser irradiation chamber 7 accommodates a base 72, and a stage 71 disposed on the base 72. In the laser annealing device 1, a silicon film is irradiated with laser light while the substrate 8 is conveyed in a +X-direction by the stage 71. In addition, a biplanar phototube 62, an OED sensor 63, an unevenness monitor 64, and a profiler camera 66 are provided as a detection unit that detects information about emitted laser light.

The annealing optical system 11 is an optical system that generates laser light for crystallizing an amorphous silicon film formed on the substrate 8 and converting the silicon film into a polysilicon film, and irradiates the amorphous silicon film with the laser light. The annealing optical system 11 includes a laser light source 2, an attenuator 3, a polarization ratio control unit 4, a beam shaping optical system 5, a vertical reflecting mirror 61, and a projection lens 65, and emits line-shaped laser light.

The laser light source 2 is a laser generating device that generates pulsed laser light as laser light for irradiating the amorphous silicon film (object to be processed). The generated laser light is laser light for forming crystallizing the amorphous film on the substrate 8 to form a crystallized film, and is, for example, gas laser light such as excimer laser light with a central wavelength of 308 nm. Alternatively, the gas laser light may be other gas lasers such as a CO2 laser without limitation to the excimer laser light.

In the laser light source 2, a gas such as xenon is sealed in a chamber, and two resonator mirrors are disposed to face each other with the gas sandwiched therebetween. One of the resonator mirrors is a total reflection mirror that reflects the entirety of light, and the other resonator mirror is a partial reflection mirror through which a part of the light is transmitted. Gas light excited by a gas repeatedly reflected between the resonator mirrors, and amplified light is emitted from the resonator mirrors as laser light. The laser light source 2 repeatedly emits pulsed laser light, for example, in a cycle from 500 Hz to 600 Hz. The laser light source 2 emits the laser light toward the attenuator 3.

The attenuator 3 attenuates incident laser light to adjust the laser light to have a predetermined energy density. As characteristics, the attenuator has a transmittance indicating a ratio of emitted laser light with respect to the incident laser light, and the transmittance is configured to be variable on the basis of a signal from the control device 9. The attenuator 3 is provided in the middle of an optical path ranging from the laser light source 2 to the beam shaping optical system 5. The attenuator 3 attenuates the laser light emitted from the laser light source 2 in correspondence with the transmittance.

An energy density (E) emitted from the attenuator 3 becomes a value (E=E0×T) obtained by multiplying an energy density (E0) of the laser light emitted from the laser light source 2 by a transmittance (T) of the attenuator 3. Although details will be described later, the control device 9 specifies (derives) and changes the transmittance of the attenuator 3 so that the energy density emitted from the attenuator 3 becomes an optical energy density.

The polarization ratio control unit 4 is disposed on an emission side of the attenuator 3. For example, the polarization ratio control unit 4 is constituted by a ½ wavelength plate (λ/2 plate) and a polarization beam splitter, and changes a polarization ratio between a P-polarized wave and an S-polarized wave of incident laser light. That is, the polarization ratio of the laser light emitted from the attenuator 3 is changed by the polarization ratio control unit 4. The polarization ratio control unit 4 is configured to change (vary) the polarization ratio on the basis of a control signal output from the control device 9.

In a case of changing the transmittance of the attenuator 3, the polarization ratio of the laser light emitted from the attenuator 3 is changed in correspondence with the transmittance. In contrast, the control device 9 controls the polarization ratio of the laser light emitted from the polarization ratio control unit 4 to be constant by changing the polarization ratio of the polarization ratio control unit 4 in correspondence with the changed transmittance.

When changing the polarization ratio of the polarization ratio control unit 4, the control device 9 may refer to information (polarization ratio table) stored in a storage unit 92 of the control device 9, for example, in a table format, and may specify (derive) the polarization ratio in correspondence with the transmittance. In the polarization ratio table, each polarization ratio corresponding to each transmittance is defined.

The laser light emitted from the polarization ratio control unit 4 is incident to the beam shaping optical system 5, and the beam shaping optical system 5 shapes the incident laser light to generate laser light with a beam shape suitable for irradiation of the silicon film. The beam shaping optical system 5 generates a line beam with a line shape along the Y-direction.

In the beam shaping optical system, for example, one beam is divided into a plurality of beams (a plurality of line beam arranged in the Z-direction), for example, by a homogenizer constituted by a lens array. After division into the plurality of beams, the beams are combined by a condenser lens to form a line beam shape. The beam shaping optical system emits the generated (shaped) line-shaped laser light to the vertical reflecting mirror 61.

The vertical reflecting mirror 61 is a rectangular reflection mirror extending in the Y-direction and reflects the laser light that is the plurality of line beams generated by the beam shaping optical system. For example, the vertical reflecting mirror 61 is a dichroic mirror and is a partial reflection mirror through which partial light is transmitted. The vertical reflecting mirror 61 generates reflected light by reflecting the line-shaped laser light, and allows a part of the line-shaped laser light to be transmitted therethrough to generate transmitted light. The vertical reflecting mirror 61 irradiates the silicon film on the substrate 8 with the laser light that is the reflected light, and emits the laser light that is transmitted light, for example, to a pulse measuring device such as a biplanar phototube.

The projection lens 65 is disposed on an upper side of the substrate 8. The projection lens 65 includes a plurality of lenses for projecting the laser light to the substrate 8, that is, the silicon film. The projection lens 65 condenses the laser light to the substrate 8. The laser light forms a line-shaped irradiation region along the Y-direction on the substrate 8. That is, on the substrate 8, the laser light becomes a line beam in which the Y-direction is set as a longitudinal direction. In addition, the silicon film is irradiated with the laser light while the substrate 8 is conveyed in the +X-direction. According to this, it is possible to irradiate a strip-shaped region in which a length of the irradiation region in the Y-direction is set as a width with the laser light.

The line beam-shaped laser light emitted to the vertical reflecting mirror 61 has a beam shape with a wide minor axis width, that is, after being emitted from the condenser lens, the minor axis width is slightly expanded and the beam shape is distorted. The laser light reflected by the vertical reflecting mirror 61 passes through the projection lens 65 and is shaped into line beam-shaped laser light of which the minor axis width is approximately ⅕ times.

The biplanar phototube 62 is provided at an end of the annealing optical system 11 in adjacent to the beam shaping optical system, and detects a pulse waveform of the laser light emitted from the laser light source 2 on the basis of the transmitted light transmitted through the vertical reflecting mirror 61. The biplanar phototube 62 outputs (transmits) the detected pulse waveform to the control device 9.

The OED sensor 63 includes an optical sensor, detects reflected light (reflected light reflected from the substrate 8) of light emitted from a light source (a separate light source) separate from the laser light source 2 to acquire information about a crystal surface on the substrate 8. The OED sensor 63 outputs detected luminance (detection value) of the reflected light that is detected to the control device 9 (transmits the luminance as a signal).

The unevenness monitor 64 includes a line camera, images a region of interest of the substrate 8 irradiated with the laser light by using the line camera, and detects average luminance of the region of interest included in a captured image to acquire information about scattered light with a surface shape of the substrate 8. The unevenness monitor 64 outputs the detected average luminance (detection value) of the substrate 8 (region of interest) to the control device 9 (transmits the average luminance as a signal).

The profiler camera 66 is a sensor (line beam sensor) that detects information about a shape of the laser light shaped into a line beam shape by the projection lens 65, and is, for example, a beam profiler. For example, the profiler camera 66 is provided a side surface portion of the stage 71, and is aligned so that an upper surface of the profiler camera 66 and the substrate 8 mounted on the stage 71 are at the same height. The upper surface of the profiler camera 66 is irradiated with the laser light shaped into a line beam shape by the annealing optical system 11. For example, the profiler camera 66 includes an imaging unit such as a CMOS camera, and images the laser light shaped into a line beam shape with the imaging unit to acquire information (data) such as an image (captured image) about a shape of the laser light. The profiler camera 66 may detect, for example, information about axis widths of a minor axis shape and a major axis shape of the rectangular line beam, distortion or depression of axial lines, an inclination when stereoscopically viewing the line beam, an angle between adjacent surfaces, or a curvature as the information about the shape of the laser light shaped into a line beam shape. The profiler camera 66 may further detect information about a raw beam shape before being shaped into the line beam. In addition to the profiler camera 66 according to this embodiment, a line beam sensor that acquires information about the shape of the laser light may be provided, for example, in the vicinity of the biplanar phototube 62 in a state in which a Y-axis direction is set to be different from the Y-axis direction of the biplanar phototube 62.

The control device 9 is an information processing device such as a PC and a server device that performs overall or integrated control or management of the laser annealing device 1. The control device 9 includes a control unit 91, a storage unit 92, a communication unit 93, and an input/output I/F 94, and is connected to a control device (another control device) that controls the laser light source 2 or respective optical systems in the annealing optical system 11 in a communication possible manner through the communication unit 93 or the input/output I/F 94. The control device 9 is connected to various measurement devices such as a pulse measurement device and a light detector included in the laser annealing device 1 in a communication possible manner, and performs various kinds of control on the laser light source 2 or the annealing optical system 11 on the basis of measurement data output from the various measurement devices.

The control unit 91 includes arithmetic operation devices such as one or a plurality of central processing units (CPU), micro-processing units (MPU), and graphics processing units (GPU) with a time measurement function, and reads out and executes a program P (program product) stored in the storage unit 92 to perform various kinds of information processing, and control processing on the laser light source 2 or the respective optical systems included in the annealing optical system 11.

The storage unit 92 includes a volatile storage region such as a static random access memory (SRAM), a dynamic random access memory (DRAM), and a flash memory, and a non-volatile storage region such as an EEPROM and a hard disk. The storage unit 92 stores the program P (program product) and data to be referred to during processing in advance. The program P stored in the storage unit 92 may be a program P (program product) that is read out from a recording medium 920 readable by the control unit 91 and is stored in the storage unit 92. In addition, the program P may be a program (program product) that is downloaded from an external computer (not illustrated) connected to a communication network (not illustrated) and is stored in the storage unit 92. The storage unit 92 stores an actual state file of the learning model 921 to be described later. The actual state file of the learning model 921 may be configured as a module included in the program P (program product).

For example, the communication unit 93 is a communication module or a communication interface conforming to an Ethernet (registered trademark) standard, and an Ethernet cable is connected to the communication unit 93. The communication unit 93 is not limited to a case of a wire such as the Ethernet cable, and may be, for example, a communication interface corresponding to radio communication such as a short range radio communication module such as Wi-Fi (registered trademark) and Bluetooth (registered trademark), or a wide range radio communication module such as 4G and 5G. The control device 9 may communicate with a product server SS connected to, for example, the external network GN through the communication unit 93.

For example, the input/output I/F 94 is a communication interface conforming to a communication standard such as RS232C, a USB, or the like. An input device such as a keyboard or a display device 941 such as a liquid crystal monitor is connected to the input/output I/F 94. The control device 9 may acquire various detection values from a detection unit such as the biplanar phototube 62, the OED sensor 63, the unevenness monitor 64, the profiler camera 66, or the like through the input/output I/F 94.

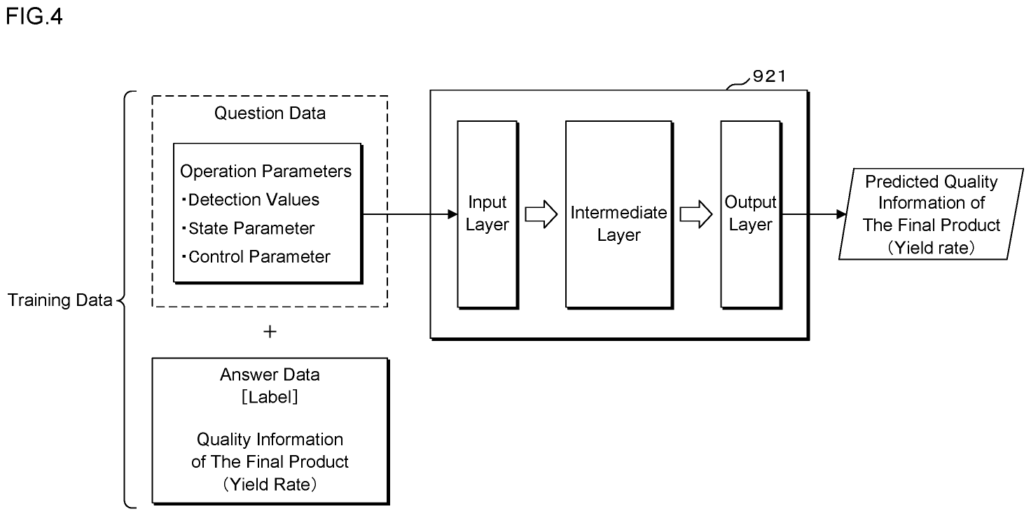

FIG. 4 is an explanatory view illustrating an example of the learning model 921. The control unit 91 of the control device 9 trains a neural network by using training data, and generates the learning model 921 that outputs quality information (predicted quality information) of a product including the substrate 8 irradiated with laser light in a case where operation parameters of the laser annealing device 1 are input. The predicted quality information is quality information predicted (estimated) by the learning model 921.

The operation parameters include detection values (parameters) from detection units such as the OED sensor 63 provided in the laser annealing device 1. The detection values are detected in a predetermined cycle, and the operation parameters may include a standard deviation or an average value of a plurality of detection values detected in the predetermined cycle. The product including the substrate 8 irradiated with the laser light is a final product of a portable terminal such as a liquid crystal monitor and a smartphone. The quality information of the final product includes, for example, a yield rate, frequency of occurrence of a defect, or a defect occurrence site as information about a detected defect of the substrate 8 when the substrate 8 is provided in the final product. In addition, the quality information may include, for example, qualitative information such as evaluation information given by a quality manager of a final product factory or the like.

The operation parameters may further include a parameter (state parameter) about a state of the laser annealing device 1, and a parameter (control parameter) about control of the laser annealing device 1 in addition to the detection values from the detection units such as the OED sensor 63. For example, the state parameter includes a parameter about a state of the laser light source 2, and a parameter about a state of the laser irradiation chamber 7 (process chamber) in which the substrate 8 is mounted. For example, the control parameter includes a parameter about control of the laser light source 2, a parameter about control of an optical system (annealing optical system 11) that shapes the laser light emitted from the laser light source 2, and a parameter about control of the laser irradiation chamber 7 (process chamber) in which the substrate 8 is mounted.

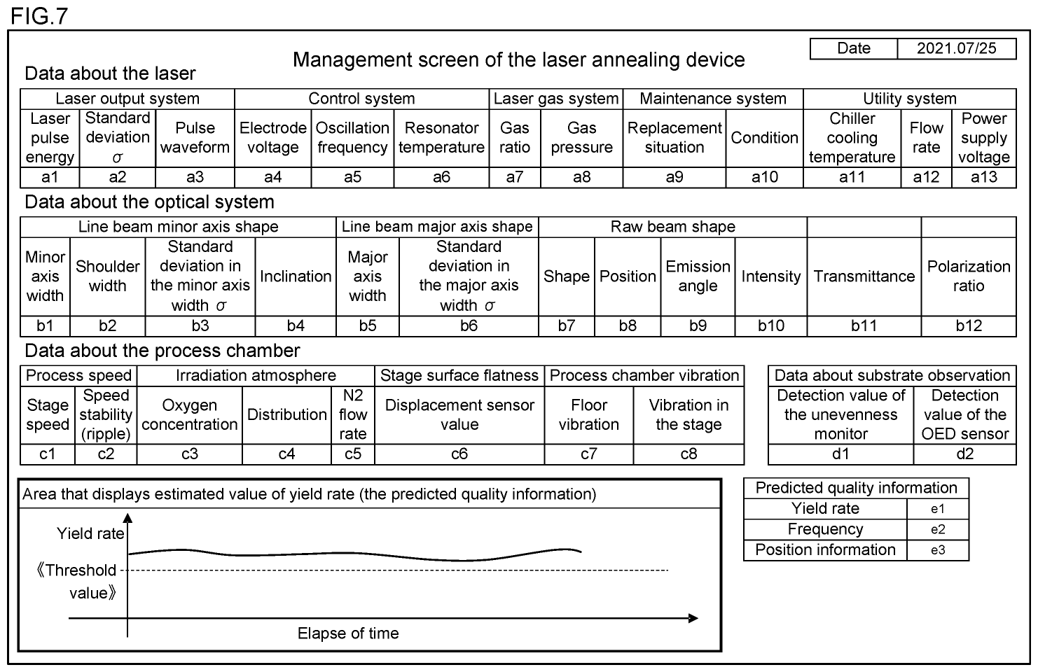

The various parameters included in the operation parameters are not limited to the above-described contents, and for example, all pieces of data included in a management screen (FIG. 7) of the laser annealing device 1 to be described later may be data included in the operation parameters. The control unit 91 of the control device 9 acquires detection values from detection units such as the OED sensor 63, various sensors such as a temperature sensor, a vibration sensor, a pressure sensor, and a camera provided at respective sites of the laser annealing device 1, and refers to operation log data and the like stored in the storage unit 92 to acquire the operation parameters.

The training data consists of question data consisting of the operation parameters including the detection values from the detection units such as the OED sensor 63, the state parameters, and the control parameters, and answer data consisting of product quality information including the yield rate and the like, and the question data and the answer data are stored in the storage unit 92 of the control device 9 in association with each other. Original data serving as the question data of the training data can be generated, for example, by integrating operation record data of a plurality of the laser annealing devices 1.

Original data serving as the answer data of the training data can be acquired from the product server SS that stores and manages quality information and the like of a final product including the substrate 8 processed by the laser annealing device 1 as described above, for example, through the external network GN. Alternatively, the control device 9 of the laser annealing device 1 may acquire the quality information with reference to a storage medium storing the quality information of the final product.

It is assumed that the neural network (learning model 921) trained by using the training data is used as a program module that is a part of artificial intelligent software. The learning model 921 is used in the control device 9, and a neural network system is configured by executing the learning model 921 by the control device 9 having arithmetic operation processing capability in this manner.

The learning model 921 consists of a deep neural network (DNN), and includes an input layer that accepts an input of the operation parameters including a detection value and the like, an intermediate layer that extracts a feature amount of the operation parameters, and an output layer that outputs quality information (predicted quality information).

The input layer includes a plurality of neurons which accept input of the operation parameters including the detection value and the like, and delivers an input value to the intermediate layer. The intermediate layer is defined by using an activation function such as a ReLu function and a sigmoid function, includes a plurality of neurons which extract a feature amount of each value that is input, and delivers an extracted feature amount to the output layer. Parameters such as a weighting coefficient and a bias value of the activation function are optimized by using an error back-propagation method. For example, the output layer consists of a fully connected layer, and outputs quality information (predicted quality information) including a yield rate and the like on the basis of the feature amount output from the intermediate layer.

In this embodiment, although the learning model 921 is assumed to be the DNN, there is no limitation thereto. The learning model 921 may be constructed by other learning algorithms such as a neural network, a transformer, a recurrent neural network (RNN), a long-short term model (LSTM), a CNN, a support vector machine (SVM), a Bayesian network, linear regression, a regression tree, multiple regression, random forest, and ensemble other than the DNN.

Although the control device 9 included in the laser annealing device 1 is assumed to generate the learning model 921, there is no limitation thereto. The learning model 921 may be trained and generated by an external server device such as a cloud server other than the control device 9. Although the learning model 921 is assumed to be used in the control device 9, there is no limitation thereto. For example, the control device 9 may communicate with a cloud server or the like that is connected to the Internet or the like through the communication unit 93, and may acquire the predicted quality information (the yield rate or the like) output by the learning model 921 provided in the cloud server.

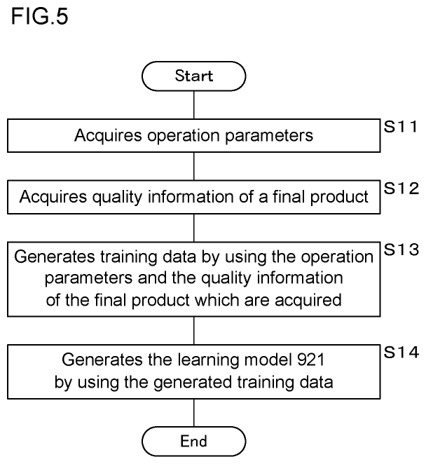

FIG. 5 is a flowchart illustrating an example of a procedure of the control unit 91 (when training the learning model 921). The control unit 91 of the control device 9 included in the laser annealing device 1 accepts operator's operation with a keyboard or the like connected to, for example, an input/output, and performs the following processing on the basis of the accepted operation.

The control unit 91 of the control device 9 acquires operation parameters (S11). The control unit 91 of the control device 9 acquires detection values from detection units such as the OED sensor 63, various sensors such as a temperature sensor, a vibration sensor, a pressure sensor, and a camera provided at respective sites of the laser annealing device 1, and refers to operation log data and the like stored in the storage unit 92 to acquire operation parameters including a plurality of pieces of the data.

The control unit 91 of the control device 9 acquires quality information of a final product (S12). The control unit 91 of the control device 9 acquires the quality information from the product server SS that stores and manages the quality information and the like of the final product including the substrate 8 processed by the laser annealing device 1. Alternatively, the control device 9 of the laser annealing device 1 may acquire the quality information with reference to a storage medium that stores the quality information of the final product.

The control unit 91 of the control device 9 generates training data by using the operation parameters and the quality information of the final product which are acquired (S13). The control unit 91 of the control device 9 generates training data in which the operation parameters are set as question data and the quality information is set as answer data. When generating the training data, the control unit 91 of the control device 9 may perform standard deviation processing, averaging processing, standardization processing, dimension reduction processing, or the like by using detection values at a plurality of points of time.

The control unit 91 of the control device 9 generates the learning model 921 by using the generated training data (S14). The control unit 91 of the control device 9 generates the learning model 921, for example, by training a neural network by using the generated training data.

In a case where a plurality of final product factories from which the substrate 8 is shipped exist, the control unit 91 of the control device 9 may generate a different learning model 921 in correspondence with each of the final product factories. Alternatively, the control unit 91 of the control device 9 may generate a different learning model 921 in correspondence with a category or a type of the final product including the substrate 8. Alternatively, a different learning model 921 may be generated in correspondence with a combination of the final product factory and the category of the final product or the like.

In a case where management criteria of the quality information acquired from the product server SS of the respective final product factories are different, or in a case where the quality information includes qualitative evaluation information or the like, the control unit 91 of the control device 9 may perform normalization, standardization, averaging, or the like on the quality information acquired and aggregated from the respective final product factories. The control unit 91 of the control device 9 may generate the learning model 921 that is generally applicable to the individual final product factories by using the quality information subjected to the normalization or the like.

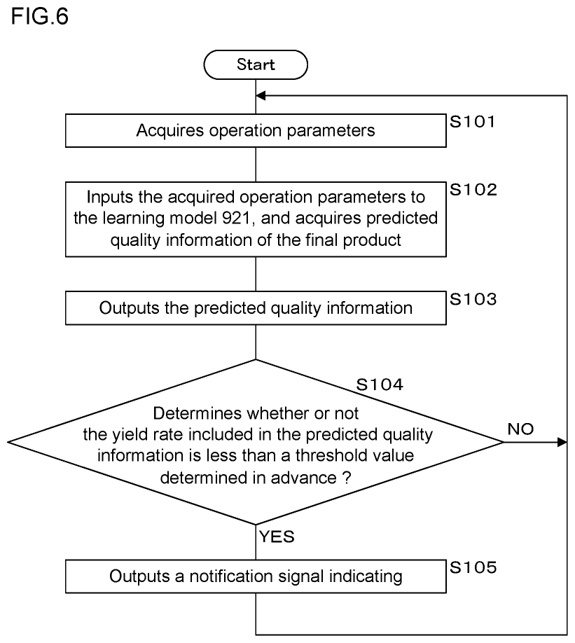

FIG. 6 is a flowchart illustrating an example of a procedure of the control unit 91 (when operating the learning model 921). The control unit 91 of the control device 9 included in the laser annealing device 1 accepts operator's operation with a keyboard or the like connected to, for example, an input/output, and performs the following processing on the basis of the accepted operation.

The control unit 91 of the control device 9 acquires operation parameters (S101). The control unit 91 of the control device 9 acquires detection values from detection units such as the OED sensor 63, various sensors such as a temperature sensor, a vibration sensor, a pressure sensor, and a camera provided at respective sites of the laser annealing device 1, and refers to operation log data and the like stored in the storage unit 92 to acquire (generate) operation parameters including a plurality of pieces of the data.

The control unit 91 of the control device 9 inputs the acquired operation parameters to the learning model 921, and acquires predicted quality information of the final product (S102). The control unit 91 of the control device 9 inputs the acquired operation parameters to the learning model 921. The learning model 921 outputs (estimates) the predicted quality information of the final product such as a yield rate in correspondence with the input operation parameters. The control unit 91 of the control device 9 can derive the predicted quality information by acquiring the predicted quality information (yield rate or the like) output from the learning model 921.

The control unit 91 of the control device 9 outputs the predicted quality information of the final product which is acquired from the learning model 921 (S103). The control unit 91 of the control device 9 associates the predicted quality information of the final product which is acquired from the learning model 921 and the operation parameters with each other, and outputs the predicted quality information and the operation parameters, for example, to the display device 941 to notify a manager of the laser annealing device 1 or the like with the predicted quality information of the final product such as the yield rate estimated from the operation parameters.

The control unit 91 of the control device 9 determines whether or not the yield rate included in the predicted quality information is less than a threshold value determined in advance (S104). The threshold value for the yield rate included in the predicted quality information is stored, for example, in the storage unit 92 of the control device 9. The control unit 91 of the control device 9 refers to the threshold value stored in the storage unit 92, and determines whether or not the yield rate included in the predicted quality information is less than the threshold value.

In a case where the yield rate is not less than the threshold value (S104: NO), that is, the yield rate included in the predicted quality information is equal to or greater than the threshold value, the control unit 91 of the control device 9 performs loop processing to execute the processing in S101 again. In a case where the yield rate is not less than the threshold value, that is, the yield rate is equal to or greater than the threshold value, the control unit 91 of the control device 9 determines that the current operation parameters are appropriate, and performs loop processing to execute the processing in S101 again.

In a case where the yield rate is less than the threshold value (S104: YES), the control unit 91 of the control device 9 outputs a notification signal indicating that the yield rate is less than the threshold value (S105). In a case where the yield rate is less than the threshold value, the control unit 91 of the control device 9 determines that the current operation parameters are inappropriate (not suitable), and outputs a notification signal indicating that the yield rate is less than the threshold value, for example, to the display device 941, a portable terminal of the manager of the laser annealing device 1, or the like.

After executing the processing in S105, the control unit 91 of the control device 9 may perform loop processing to execute the processing in S101 again so as to continue monitoring about appropriateness of the operation parameters from the viewpoint of the quality information of the final product.

FIG. 7 is a view illustrating an example of a management screen of the laser annealing device 1. The control unit 91 of the control device 9 generates a management screen (screen data) shown as an example in this embodiment by using the acquired operation parameters and the derived (estimated) predicted quality information, and outputs the management screen, for example, to the display device 941 or the like.

The management screen of the laser annealing device 1 includes respective display areas which display data about a laser, data about an optical system, data about a process chamber, and data about substrate observation in a list format, and an area that displays the predicted quality information that is estimated.

The display area of the data about the laser includes display sections of a laser output system, a control system, a laser gas system, a maintenance system, and a utility system. A laser pulse energy, a standard deviation (o) of the laser pulse energy, and a pulse waveform are displayed in the laser output system display section. An electrode voltage, an oscillation frequency, and a resonator temperature are displayed in the control system display section. A gas ratio and a gas pressure are displayed in the laser gas system display section. A replacement situation and a condition of consumables are displayed in the maintenance system display section. A chiller cooling temperature, a flow rate, and a power supply voltage are displayed in the utility system display section.

The display area of the data about the optical system includes display sections of a line beam minor axis shape, a line beam major axis shape, and a raw beam shape, and display items of a transmittance and a polarization ratio. A minor axis width, a shoulder width, a standard deviation (o) in the minor axis width, and an inclination are displayed in the line beam minor axis shape display section. A major axis width, and a standard deviation (o) in the major axis width are displayed in the line beam major axis shape display section. A shape, a position, an emission angle, and an intensity are displayed in the raw beam shape display section. A transmittance of the attenuator 3 is displayed in the transmittance display item. A polarization ratio of the polarization ratio control unit 4 is displayed in the polarization ratio display item.

The display area of the data about the process chamber includes display items of a process speed, an irradiation atmosphere, stage surface flatness, and process chamber vibration. A stage speed and speed stability (ripple) are displayed in the process speed display section. An oxygen concentration, a distribution, and a nitrogen (N2) flow rate are displayed in the irradiation atmosphere display section. A displacement sensor value is displayed in the stage surface flatness display section. Floor vibration, and vibration in the stage are displayed in the process chamber vibration. The display area of data about substrate observation includes display items of a detection value of the unevenness monitor 64, and a detection value of the OED sensor 63.

The area that displays the predicted quality information that is estimated includes a graph display area where a variation in the yield rate with the elapse of time, and a list display area where the predicted quality information that is estimated is shown in a list format. The horizontal axis of the graph displaying the variation in the yield rate with the elapse of time represents elapsed time, and the vertical axis represents the yield rate. A threshold value is set to the yield rate in advance. The list display area that shows the predicted quality information includes display items of the yield rate, frequency of a defect, and position information of the defect on the substrate 8.

Since the operation parameters acquired in correspondence with the operation of the laser annealing device 1, and the yield rate (the predicted quality information of the final product provided in the substrate 8) derived (estimated) on the basis of the operation parameters are screen-displayed in association with each other, visibility by the manager of the laser annealing device 1 or the like can be improved.

According to this embodiment, predicted quality information (predicted quality information of the final product including the substrate 8) derived (estimated) on the basis of the operation parameters including detection values acquired by detection units is acquired and output by using the learning model 921. According to this, from the viewpoint of the quality information of the product including the substrate 8 irradiated with the laser light, appropriateness of the detection value (operation parameters) is determined (state diagnosis), and the manager of the laser annealing device 1 (laser irradiation device) or the like can be notified with the detection values. That is, the operation parameters and the predicted quality information of the product are associated with each other by estimating the quality information (predicted quality information) of the product (final product) including the substrate 8 manufactured by the laser annealing device 1 (laser irradiation device) on the basis of the operation parameters including the detection values, the operation parameters are optimized in correspondence with the association, and control about laser light can be effectively performed.

According to this embodiment, in a case where the yield rate of the product which is included in the predicted quality information derived by using the learning model 921 is less than a threshold value that is determined in advance, since a notification signal indicating the gist is output, it is possible to urge the manager of the laser annealing device 1 or the like to make a determination as to whether to continue operation of the laser annealing device 1.

According to this embodiment, since the detection units include various kinds of detection units such as the OED sensor 63, the unevenness monitor 64, the biplanar phototube 62, and the profiler camera 66, a plurality of kinds of detection values obtained by the detection units can be used as input data to the learning model 921, and estimation accuracy by the learning model 921 can be improved. Since the operation parameters input to the learning model 921 include a standard deviation calculated on the basis of a plurality of detection values detected in a predetermined cycle, estimation accuracy by the learning model 921 can be improved.

According to this embodiment, since the operation parameters input to the learning model 921 include a parameter about a state of the laser light source 2, and a parameter about a state of the laser irradiation chamber 7 (process chamber) in which the substrate 8 is mounted, estimation accuracy of the learning model 921 can be improved.

According to this embodiment, since the operation parameters input to the learning model 921 include a parameter about control of the laser light source 2, a parameter about control of the optical systems, and a parameter about control of the laser irradiation chamber 7 (process chamber), estimation accuracy by the learning model 921 can be improved.

### Embodiment 2

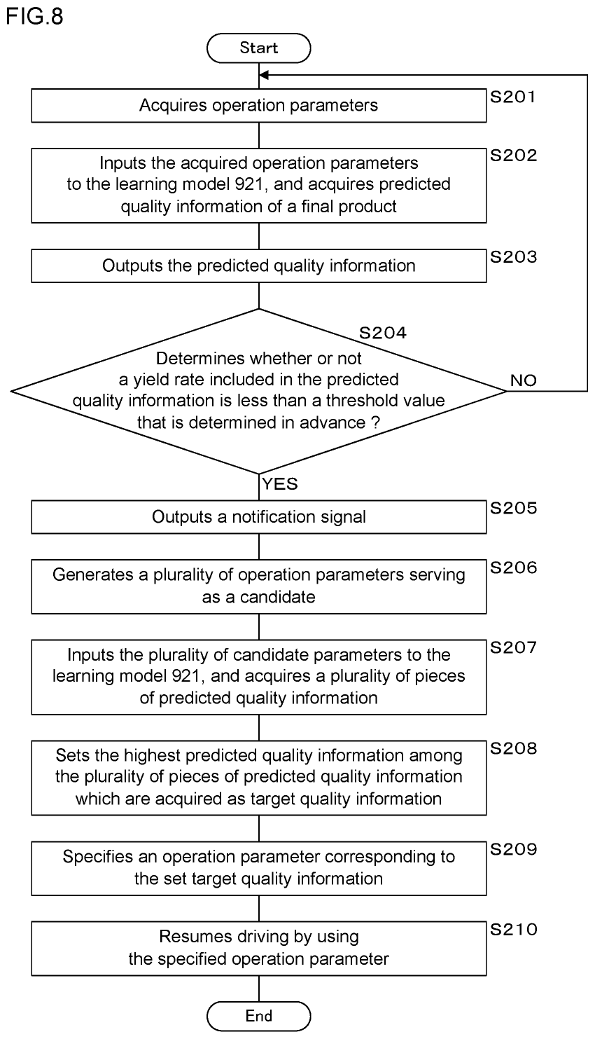

FIG. 8 is a flowchart illustrating an example of a procedure (while driving the operation parameters) of the control unit 91 according to Embodiment 2. The control unit 91 of the control device 9 included in the laser annealing device 1 accepts operator's operation with a keyboard or the like connected to, for example, an input/output, and performs the following processing on the basis of the accepted operation.

The control unit 91 of the control device 9 acquires operation parameters (S201). The control unit 91 of the control device 9 inputs the acquired operation parameters to the learning model 921, and acquires predicted quality information of a final product (S202). The control unit 91 of the control device 9 outputs the predicted quality information of the final product which is acquired from the learning model 921 (S203). The control unit 91 of the control device 9 determines whether or not a yield rate included in the predicted quality information is less than a threshold value that is determined in advance (S204). The control unit 91 of the control device 9 outputs a notification signal indicating that the yield rate is less than the threshold value (S205). The control unit 91 of the control device 9 performs processing from S201 to S205 in a similar manner as in the processing from S101 to S105 in Embodiment 1.

After executing the processing in S205, when the control unit 91 of the control device 9 generates a plurality of operation parameters serving as a candidate when changing the operation parameters (S206). With respect to the current operation parameters, the control unit 91 of the control device 9 generates a plurality of operation parameters in which values included in the operation parameters are made different step by step within a predetermined range as operation parameters serving as a candidate (candidate parameters). When generating the plurality of candidate parameters, the control unit 91 of the control device 9 may change, for example, a control parameter of the laser light source 2 such as an electrode voltage and an oscillation frequency, a control parameter of the annealing optical system 11 such as a transmittance and a polarization ratio, or a control parameter about the laser irradiation chamber 7 such as a process speed step by step on the basis of the current operation parameters, and may combine various parameters changed step by step.

The control unit 91 of the control device 9 inputs the plurality of candidate parameters to the learning model 921, and acquires a plurality of pieces of predicted quality information (S207). The control unit 91 of the control device 9 can acquire a plurality of pieces of predicted quality information corresponding to the candidate parameters by repeatedly inputting the plurality of generated candidate parameters to the learning model 921.

The control unit 91 of the control device 9 sets the highest predicted quality information among the plurality of pieces of predicted quality information which are acquired as target quality information (S208). In each of the plurality pieces of predicted quality information estimated on the basis of the candidate parameters, the control unit 91 of the control device 9 sets, for example, predicted quality information with the highest yield rate as target quality information. It is needless to say that the set target quality information (target yield rate) is higher than predicted quality information (yield rate) output from (estimated by) the learning model 921 in accordance with the current operation parameters.

The control unit 91 of the control device 9 specifies an operation parameter corresponding to the set target quality information (S209). The control unit 91 of the control device 9 derives an operation parameter corresponding to the target quality information by specifying an operation parameter that is input data when the learning model 921 outputs (estimates) the target quality information.

The control unit 91 of the control device 9 resumes driving by using the specified operation parameter (S210). The control unit 91 of the control device 9 changes irradiation conditions by changing the current operation parameters to the operation parameters specified in S209 when the laser annealing device 1 replaces the substrate 8, or replaces a cassette accommodating a plurality of the substrates 8, and resumes irradiation of the substrate 8 with the laser light.

According to this embodiment, the control unit 91 of the control device 9 sets target quality information with quality higher than the predicted quality information estimated by the learning model 921 on the basis of the current operation parameters. With respect to the current operation parameters, the control unit 91 of the control device 9 generates a plurality of operation parameters in which values included in the operation parameters are made different step by step within a predetermined range as operation parameters (candidate parameters) serving as a candidate. The control unit 91 of the control device 9 can acquire a plurality of pieces of predicted quality information corresponding to the candidate parameters by inputting the plurality of generated candidate parameters to the learning model 921.

In each of the plurality pieces of predicted quality information estimated on the basis of the candidate parameters, the control unit 91 of the control device 9 sets, for example, predicted quality information with the highest yield rate as target quality information, and specifies operation parameters which are input data when the learning model 921 outputs (estimates) the target quality information. Since the control unit 91 of the control device 9 performs control about irradiation of the substrate 8 with the laser light on the basis of the operation parameters corresponding to the target quality information, the yield rate of the final product including the substrate 8 manufactured by the laser annealing device 1 is improved, and thus quality information of the final product can be raised.

### OTHER EMBODIMENTS

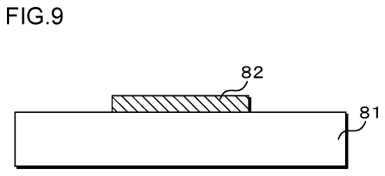

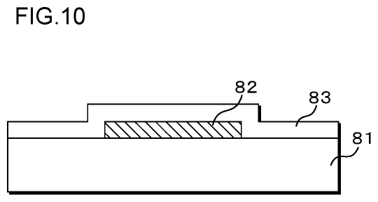

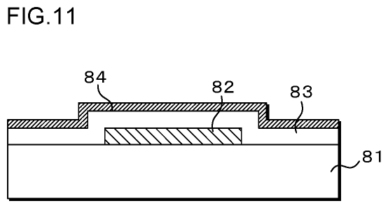

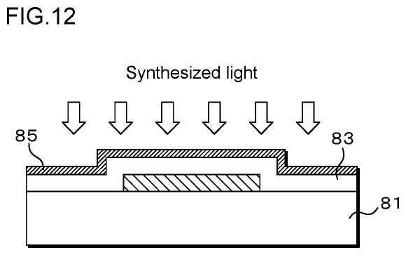

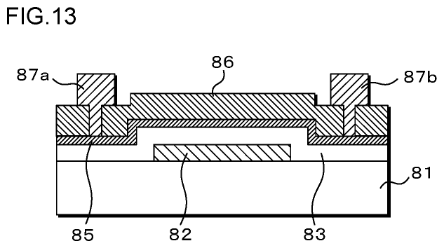

FIG. 9, FIG. 10, FIG. 11, FIG. 12, and FIG. 13 are process cross-sectional views illustrating a method for manufacturing a semiconductor device according to other embodiments (method for manufacturing a semiconductor device). As the other embodiments, description will be given of a method for manufacturing a semiconductor device using the laser annealing device 1 according to the above-described embodiments. In the following methods for manufacturing a semiconductor device, annealing processing using the laser annealing device 1 according to Embodiment 1 and Embodiment 2 is performed in a process of crystallizing an amorphous semiconductor film.

The semiconductor device is a semiconductor device including a thin film transistor (TFT), and in this case, an amorphous silicon film 84 is irradiated with laser light for crystallization, and a polysilicon film 85 can be formed. The polysilicon film 85 is used as a semiconductor layer including a source region, a channel region, and a drain region of the TFT.

The laser annealing device 1 according to the above-described embodiments is suitable for manufacturing a TFT array substrate. Hereinafter, description will be given of a method for manufacturing a semiconductor device including the TFT.

First, as illustrated in FIG. 9, a gate electrode 82 is formed on a glass substrate 81 (substrate 8). As the gate electrode 82, for example, a metal thin film containing aluminum or the like can be used. Next, as illustrated in FIG. 10, a gate insulation film 83 is formed on the gate electrode 82. The gate insulation film 83 is formed to cover the gate electrode 82. Then, as illustrated in FIG. 11, an amorphous silicon film 84 is formed on the gate insulation film 83. The amorphous silicon film 84 is disposed to overlap the gate electrode 82 with the gate insulation film 83 interposed therebetween.

The gate insulation film 83 is a silicon nitride film (SiNx), a silicon oxide film (SiO2 film), a stacked film thereof, or the like. Specifically, the gate insulation film 83 and the amorphous silicon film 84 are continuously formed by a chemical vapor deposition (CVD) method. The glass substrate 81 with the amorphous silicon film 84 becomes a semiconductor film in the laser annealing device 1 (laser irradiation device).

Next, as illustrated in FIG. 12, the amorphous silicon film 84 is irradiated with the laser light by using the above-described laser annealing device 1 to crystallize the amorphous silicon film 84, thereby forming the polysilicon film 85. According to this, the polysilicon film 85 in which silicon is crystallized is formed on the gate insulation film 83.

Next, as illustrated in FIG. 13, an interlayer insulation film 86, a source electrode 87a, and a drain electrode 87b are formed on the polysilicon film 85. The interlayer insulation film 86, the source electrode 87a, and the drain electrode 87b can be formed by using a general photolithography method or a general film formation method. The subsequent manufacturing processes are different depending on a device that is finally manufactured, and thus description thereof will be omitted.

When using the above-described method for manufacturing a semiconductor device, it is possible to manufacture a semiconductor device provided with the TFT including a polycrystalline semiconductor film. The semiconductor device is suitable for control of a high-definition display such as an organic electro luminescence (EL) display. As described above, since unevenness of the polysilicon film 85 is suppressed, it is possible to manufacture a display device with excellent display characteristics with high productivity.

When performing the series of processing processes, the control device 9 of the laser annealing device 1 derives predicted quality information of a final product including the substrate 8 on the basis of the acquired operation parameters, and outputs the predicted quality information to the display device 941. According to this, the operation parameters and the predicted quality information of the product are associated with each other, monitoring about appropriateness of the operation parameters from the viewpoint of the quality information of the final product can be performed, and optimization of the operation parameters is supported. Accordingly, control about the laser annealing device 1 can be efficiently performed.

In addition, the present disclosure is not limited to the above-described embodiments, and can be appropriately changed within a range not departing from the gist. For example, a microcrystal silicon film may be formed by irradiating the amorphous silicon film 84 with the laser light without limitation to the example in which the polysilicon film 85 is formed by irradiating the amorphous silicon film 84 with the laser light. In addition, an amorphous film other than the silicon film may be irradiated with the laser light to form a crystallized film.

The embodiments disclosed herein are illustrative in all respects, and should be considered not to be restrictive. Technical characteristics described in the respective embodiments can be combined with each other, and the scope of the invention is intended to include all modifications within a scope of the appended claims and a scope equivalent to the scope of the appended claims.

It is noted that, as used herein and in the appended claims, the singular forms “a”, “an”, and “the” include plural referents unless the context clearly dictates otherwise.

### DESCRIPTION OF REFERENCE NUMERALS

GN External network
SS Product server
1 Laser annealing device (laser irradiation device)
11 Annealing optical system
2 Laser light source
3 Attenuator
4 Polarization ratio control unit
5 Beam shaping optical system
61 Vertical reflecting mirror
62 Biplanar phototube
63 OED sensor
64 Unevenness monitor
65 Projection lens
66 Profiler camera (line beam sensor)
7 Laser irradiation chamber
71 Stage
72 Base
8 Substrate
9 Control device
91 Control unit
92 Storage unit
920 Recording medium
P Program (program product)
921 Learning model
93 Communication unit
94 Input/output I/F
941 Display device
81 Glass substrate
82 Gate electrode
83 Gate insulation film
84 Amorphous silicon film
85 Polysilicon film
86 Interlayer insulation film
87a Source electrode
87b Drain electrode

1-10. (canceled)

11. A laser irradiation device, comprising:
a laser light source that emits laser light; and
a control unit that performs control relating to irradiation of a substrate with laser light,
wherein the control unit,
acquires operation parameters including a detection value from a detection unit provided in the laser irradiation device,
derives predicted quality information by inputting the acquired operation parameters to a learning model that outputs predicted quality information of a product including the substrate irradiated with the laser light in a case where the operation parameters are input, and
outputs the derived predicted quality information and the acquired operation parameters in association with each other.

12. The laser irradiation device according to claim 11,
wherein the predicted quality information derived by using the learning model includes information about a yield rate of the product, and
the control unit outputs a notification signal indicating that the yield rate is less than a threshold value in a case where the yield rate of the product is less than the threshold value that is determined in advance.

13. The laser irradiation device according to claim 11,
wherein the detection unit includes at least one of an OED sensor, an unevenness monitor, a biplanar phototube, and a profiler camera,
the OED sensor detects information about a crystal surface on the substrate,
the unevenness monitor detects information about scattered light in a surface shape of the substrate,
the biplanar phototube detects a pulse waveform of the laser light emitted from the laser light source, and
the profiler camera detects information about a shape of the laser light shaped in a line beam shape.

14. The laser irradiation device according to claim 11,
wherein the detection unit acquires a plurality of detection values in a predetermined cycle, and
the operation parameters include a standard deviation calculated on the basis of the plurality of detection values.

15. The laser irradiation device according to claim 11,
wherein the operation parameters include at least one of a parameter relating to a state of the laser light source, and a parameter relating to a state of a laser irradiation chamber in which the substrate is mounted.

16. The laser irradiation device according to claim 11,
wherein the operation parameters include a control parameter for controlling the laser irradiation device, and
the control parameter includes at least one of a parameter relating to control of the laser light source, a parameter relating to control of an optical system that shapes the laser light emitted from the laser light source, and a parameter relating to control of the laser irradiation chamber in which the substrate is mounted.

17. The laser irradiation device according to claim 16,
wherein the control unit,
sets target quality information with higher quality in comparison to the predicted quality information that is derived,
derives a control parameter corresponding to the target quality information that is set, and
performs control relating to irradiation of the substrate with the laser light on the basis of the derived control parameter.

18. An information processing method causing a computer to execute processing of:
acquiring operation parameters including a detection value from a detection unit provided in a laser irradiation device;
deriving predicted quality information by inputting the acquired operation parameters to a learning model that outputs predicted quality information of a product including a substrate irradiated with laser light in a case where operation parameters are input; and
outputting the derived predicted quality information and the acquired operation parameters in association with each other.

19. A method for generating a learning model, comprising:
acquiring operation parameters including a detection value from a detection unit provided in a laser irradiation device;
acquiring quality information of a product including a substrate processed by a laser irradiation device controlled by using the operation parameters; and
generating a learning model that outputs the quality information of the product including the substrate processed by the laser irradiation device in a case where the operation parameters are input by using training data including question data consisting of the acquired operation parameters, and answer data consisting of the acquired quality information.
